(19) United States
(12) Patent Application Publication
(10) Pub. No.: US 2025/0116726 A1
(43) Pub. Date: Apr. 10, 2025

(54) ELECTRONIC COMPONENT INTENDED TO BE PLACED ON BOARD A VEHICLE

(71) Applicant: Valeo eAutomotive Germany GmbH, Erlangen (DE)

(72) Inventors: Larbi Bendani, Cergy Pontoise (FR); Jean-Noel Fiorina, Cergy Pontoise (FR); Sofiane Sebiane, Cergy Pontoise (FR)

(73) Assignee: Valeo eAutomotive Germany GmbH, Erlangen (DE)

(21) Appl. No.: 18/906,665

(22) Filed: Oct. 4, 2024

(30) Foreign Application Priority Data
Oct. 5, 2023 (FR) 2310670

(51) Int. Cl. G01R 31/52; B60L 3/00; B60L 53/22; G01K 7/22; H02J 7/02

(52) U.S. Cl. CPC G01R 31/52; B60L 3/003; B60L 53/22; G01K 7/22; H02J 7/02; B60L 2210/10; H02J 2207/20

(57) ABSTRACT

An electronic component for charging an electrical energy storage unit, comprising a connector connected to an electrical grid configured to supply a three-phase AC voltage, an inverter/rectifier, and a fourth switching arm connected in parallel with the switching arms of the inverter/rectifier. The inverter/rectifier includes three switching arms connected in parallel. Each switching arm has two switches connected to a phase of an AC voltage. The fourth switching arm has two switches connected to the neutral of the electrical grid, and a branch connected in parallel with the switching arms, having two capacitors, and a measuring resistor connected in series with one of the capacitors. The branch and the switching arms are connected between two DC terminals. A first switch is connected in parallel with the measuring resistor and a second switch is connected in series.

The present invention relates to an electronic component intended to be placed on board a vehicle. Such a component provides, for example, a supply of electric power to a vehicle electrical energy storage unit, and is also called a “charger” for this electrical energy storage unit. The electrical energy storage unit is, for example, a battery, which can have a nominal voltage greater than 60 V, for example greater than or equal to 300 V, 400 V, 800 V, or even 1000 V. In a known example, this component comprises:
an inverter/rectifier whose input receives an AC voltage from a charging terminal and whose output supplies a DC voltage, and
a DC-to-DC converter arranged downstream of the inverter/rectifier and connected to the electrical energy storage unit.

Such an inverter/rectifier uses a plurality of controllable electronic switches such as MOSFETs or IGBTs. A failure in one of these electronic switches may lead to there being a short circuit across the terminals of this controllable electronic switch. There is a risk of tripping the charging terminal connected to the electronic component when a short circuit such as this exists. Moreover, if the electronic component is not put into a disabled state there is a risk that the next time it is connected to another charging terminal this other terminal will also trip. To avoid such a risk, it is known practice to arrange fuses between the inverter/rectifier and the connector allowing the electronic component to be connected to the charging terminal. The use of fuses gives rise to additional cost and can give rise to additional bulk. Furthermore, the use of fuses gives rise to losses and heating.

There is a need to further improve such components by overcoming all or some of the above drawbacks.

The aim of the invention is to address this need, and it does so, according to one of its aspects, by way of an electronic component for charging an electrical energy storage unit, comprising:
a connector capable of being connected to an electrical grid capable of supplying a three-phase AC voltage,
an inverter/rectifier, comprising three switching arms connected in parallel, each switching arm comprising two switches arranged on either side of a midpoint capable of being connected to a respective phase of the AC voltage,
a fourth switching arm connected in parallel with the switching arms of the inverter/rectifier, this fourth switching arm comprising two switches arranged on either side of a fourth midpoint capable of being connected to the neutral of the electrical grid, and
a branch connected in parallel with said switching arms, comprising: two capacitors arranged on either side of a fifth midpoint, and a measuring resistor connected in series with one of the capacitors,
   the branch and the switching arms being connected between two DC terminals, characterized in that a first switch is connected in parallel with the measuring resistor and in that a second switch is connected in series between the fourth and the fifth midpoint.

The presence of the measuring resistor in series with one of the capacitors belonging to the branch connected in parallel with the switching arms of the inverter/rectifier allows multiple tests to be carried out that can be used to diagnose whether a short circuit exists across the terminals of a switch of the component, be it a switch of the inverter/rectifier or one of the first and second switches mentioned above, in particular. As will also be seen hereinafter, other short circuits in the component can be detected by way of tests performed in connection with this measuring resistor. This avoids tripping the charging terminal without the need to use fuses.

The presence of the fourth switching arm in parallel with the switching arms of the inverter/rectifier, the midpoint of said fourth switching arm being capable of being connected to the neutral, allows this fourth switching arm to be used for single-phase rectification when the charging terminal supplies a single-phase voltage.

The result is a component that allows:
three-phase charging via the three phases of the AC voltage and the three switching arms of the inverter/rectifier, and
single-phase charging via the neutral of the AC voltage and the fourth switching arm a component whose state can be tested to avoid tripping the charging terminal without using fuses. The component may not have any fuses.

The inverter/rectifier can be configured to perform AC power factor correction (PFC). The inverter/rectifier comprises, for example, switches that are MOSFETs and the fourth switching arm comprises switches that are IGBTs. The choice of these switches for the fourth arm is particularly suited to a single-phase AC voltage. In a variant, the switches of the inverter/rectifier and of the fourth switching arm are of the same type, for example IGBTs only or MOSFETs only.

The measuring resistor may be connected in series with the capacitor arranged between the fifth midpoint and that one of the DC potential terminals that is earth. This position of the measuring resistor enables it to be associated with a fixed electrical potential, namely earth.

As a variant, the measuring resistor may be connected in series with the capacitor arranged between the fifth midpoint and that one of the DC potential terminals that is at a positive electrical potential different from earth.

Each of the first and second switches is, for example, an electrical engineering relay. However, the invention is not limited to such an example, other switches being possible, for example a static relay based on optical couplers and/or MOSFETs and/or IGBTs.

The electronic component can comprise a DC-to-DC converter cascaded with the fourth switching arm and the branch comprising the two capacitors and the measuring resistor.

This DC-to-DC converter comprises, for example, electrical isolation, in particular via a transformer. This transformer is, for example, a single-phase or three-phase transformer. This DC-to-DC converter comprises, in a known manner:
an inverter/rectifier connected between the two DC terminals and the primary of the transformer, and
a rectifier/inverter or diode rectifier connected between the secondary of the transformer and the electrical energy storage unit. When a rectifier/inverter is present, it can comprise MOSFETs allowing synchronous rectification.

The DC-to-DC converter is, for example, a resonant converter of LLC or CLLC type.

In all of the above, the measuring resistor may be a simple resistor, that is to say an impedance whose resistance value remains constant. As a variant, this measuring resistor may be a thermistor. This is, for example, a positive temperature coefficient thermistor, also known as a PTC. The invention is not limited to a resistor, the use of an inductor being conceivable.

Each capacitor of the branch connected in parallel with the switching arms is, for example, an electrolytic capacitor having, for example, a capacitance of between 100 μF and 1000 μF. These capacitors process, for example, low-frequency currents.

Another arm comprising only one capacitor may also be connected in parallel with the fourth switching arm. This capacitor is, for example, a capacitor whose capacitance is of the order of a few hundred nF. The aim of this capacitor is in particular to reduce high-frequency ripple. This capacitor is, for example, made of polypropylene or ceramic.

In all of the above, the component can comprise a control unit configured to:
perform a measurement on an electrical quantity associated with the measuring resistor, and
use this measurement to determine whether one of the following faults exists:
   short-circuit state of the first switch,
   short-circuit state of the second switch,
   short-circuit state of one of the switches of the fourth switching arm,
   short-circuit state of one of the switches of a switching arm of the inverter/rectifier,
   a short circuit existing between one phase of the AC voltage and the neutral, or
   a short circuit existing between two of the phases of the AC voltage, the latter being in particular three-phase.

Carrying out all or some of these tests allows the state of the electronic component to be diagnosed before it is connected to the electrical grid to charge the electrical energy storage unit. As already mentioned, the existence of short circuits in the component is detected.

Determining the fault(s) may be done while a voltage, which is not obtained via the connector, is applied to the terminals of the switching arms. This voltage is for instance obtained from the power supply of the control unit. It may have a value lying between 12 V and 24 V, being for example equal to 18 V or 20 V.

The first switch may be a precharge switch, such as a precharge relay. The measuring resistor may enable the inrush current in the capacitors of the branch, which is connected in parallel with the switching arms, to be limited. While connecting the electronic component to the electrical grid, the first switch may be open so as to limit the inrush current. Once the voltage across the terminals of the switching arms, and thus of said branch, is lying in a predefined range of values, notably between 680V and 820V, the first switch may be controlled to remain closed, so that the measuring resistor is short-circuited. The control unit may comprise a microcontroller, or an integrated circuit, for example an FPGA or an ASIC.

The control unit is, for example, configured to:
perform a sequence of measurements on the electrical quantity associated with the measuring resistor and
use these measurements to determine whether multiple instances of said faults exist, one measurement being associated with the determination of one or more of said faults.

According to this aspect of the invention, a single electrical quantity associated with the measuring resistor, repeated in a sequence, is used to perform all or some of the aforementioned tests. A single measurement can be used, for example, to determine one of the aforementioned faults. As a variant, multiple measurements may be necessary to determine whether one of the aforementioned faults exists. For example, two measurements may be necessary to determine whether a short circuit exists between two of the three phases of the AC voltage or the short-circuit state of one of the switches of the fourth switching arm.

The measurement is, for example, compared with a reference value by the control unit and, depending on the result of this comparison, the control unit determines whether or not the fault exists. From one fault to another, the reference value is, for example, different.

The sequence of measurements can comprise a number of measurements that can be used to determine whether all of the aforementioned faults exist. It is thus possible to completely dispense with fuses protecting the charging terminal and the electrical grid from the existence of one of these faults.

According to a specific example, the control unit is configured to:
perform a first measurement on the electrical quantity associated with the measuring resistor,
take this first measurement as a basis for determining whether the first switch is in a short-circuit state,
when the first switch is not in a short-circuit state, perform a second measurement on the electrical quantity associated with the measuring resistor,
take this second measurement as a basis for determining whether the second switch is in a short-circuit state or whether one of the switches of the fourth switching arm is in a short-circuit state,
when the second switch is not in a short-circuit state or the switch of the fourth switching arm is not in a short-circuit state, perform a third measurement on the electrical quantity associated with the measuring resistor,
take this third measurement as a basis for determining whether the other switch of the fourth switching arm is in a short-circuit state,
when the other switch of the fourth switching arm is not in a short-circuit state, perform a fourth measurement on the electrical quantity associated with the measuring resistor,
take this fourth measurement as a basis for determining whether one of the switches of the inverter/rectifier arranged between a midpoint and one of the DC terminals is in a short-circuit state,
when none of the switches of the inverter/rectifier arranged between a midpoint and one of the DC terminals is in a short-circuit state, perform a fifth measurement on the electrical quantity associated with the measuring resistor,
take this fifth measurement as a basis for determining whether one of the switches of the inverter/rectifier arranged between a midpoint and the other of the DC terminals is in a short-circuit state,
when none of the switches of the inverter/rectifier arranged between a midpoint and the other of the DC terminals is in a short-circuit state, perform a sixth measurement on the electrical quantity associated with the measuring resistor,
take this sixth measurement as a basis for determining whether one phase of the AC voltage is shorted to the neutral,
when no phase of the AC voltage is shorted to the neutral, perform a seventh measurement on the electrical quantity associated with the measuring resistor,
take this seventh measurement as a basis for determining whether a short circuit exists between the first phase and the second phase of the AC voltage,
when no short circuit is detected between the first phase and the second phase of the AC voltage, perform an eighth measurement on the electrical quantity associated with the measuring resistor,
take this eighth measurement as a basis for determining whether a short circuit exists between the first phase and the third phase of the AC voltage,
when no short circuit is detected between the first phase and the third phase of the AC voltage, perform a ninth measurement on the electrical quantity associated with the measuring resistor,
take this ninth measurement as a basis for determining whether a short circuit exists between the second phase and the third phase of the AC voltage.

Carrying out these nine measurements allows, for example, all the short-circuit faults likely to occur in the aforementioned inverter/rectifier, fourth switching arm and branch to be verified.

These nine measurements can be performed in the order in which they have been described above.

When the component comprises a DC-to-DC converter as mentioned above, the control unit can be configured to perform at least one additional measurement on the electrical quantity associated with the measuring resistor in order to determine the short-circuit state of a switch of the DC-to-DC converter.

The electrical quantity associated with the measuring resistor is, for example, the voltage across the terminals of this measuring resistor. Thus, measuring only the voltage across the terminals of the measuring resistor determines whether all or some of the aforementioned faults exist.

In all of the above, the component can comprise an AC filtering stage arranged in series between the connector and the inverter/rectifier. This filtering stage can be used, for example, when the AC voltage is polyphase, to filter the common-mode current and/or to filter the differential current.

In all of the above, the component can comprise a DC filtering stage arranged in series between the DC-to-DC converter and the electrical energy storage unit.

In all of the above, the electrical grid voltage can have a frequency of 50 Hz or 60 Hz and a RMS value of 230 V or 240 V. As a variant, the electrical grid voltage may be single-phase.

In all of the above, the electrical energy storage unit is, for example, a battery, which can have a nominal voltage greater than 60 V, for example greater than or equal to 300 V, 400 V, 800 V, or even 1000 V.

In all of the above, the component can be used to charge the electrical energy storage unit with a power of 7 kW, 11 kW or 22 kW, or even more.

The electronic component may or may not be grouped together in the same box with a DC-to-DC converter providing a voltage conversion between the voltage across the terminals of the electrical energy storage unit, called the “high voltage”, and the voltage of the vehicle electrical network, called the “low voltage”. As already mentioned, the high voltage is, for example, greater than 60 V, for example greater than or equal to 300 V, 400 V, 800 V, or even 1000 V, while the low voltage is, for example, equal to 12 V or 48 V.

According to another of its aspects, the invention also relates to a method, implemented in the aforementioned component, for detecting at least one of the following faults:
short-circuit state of the first switch,
short-circuit state of the second switch,
short-circuit state of one of the switches of the fourth switching arm,
short-circuit state of one of the switches of a switching arm of the inverter/rectifier,
a short circuit existing between one phase of the AC voltage and the neutral, or
a short circuit existing between two of the three phases of the AC voltage.

This method comprises the following steps:
perform a measurement on an electrical quantity associated with the measuring resistor,
take this measurement, in particular by comparing this measurement with a reference value, as a basis for determining whether or not the fault exists.

According to the method, it is possible to perform a sequence of measurements on the electrical quantity associated with the measuring resistor and to use these measurements to determine whether multiple instances of said faults exist, one measurement being associated with the determination of one or more of said faults.

The method can comprise the following steps:
perform a first measurement on the electrical quantity associated with the measuring resistor,
take this first measurement as a basis for determining whether the first switch is in a short-circuit state,
when the first switch is not in a short-circuit state, perform a second measurement on the electrical quantity associated with the measuring resistor,
take this second measurement as a basis for determining whether the second switch is in a short-circuit state or whether one of the switches of the fourth switching arm is in a short-circuit state,
when the second switch is not in a short-circuit state or the switch of the fourth switching arm is not in a short-circuit state, perform a third measurement on the electrical quantity associated with the measuring resistor,
take this third measurement as a basis for determining whether the other switch of the fourth switching arm is in a short-circuit state,
when the other switch of the fourth switching arm is not in a short-circuit state, perform a fourth measurement on the electrical quantity associated with the measuring resistor,
take this fourth measurement as a basis for determining whether one of the switches of the inverter/rectifier arranged between a midpoint and one of the DC terminals is in a short-circuit state,
when none of the switches of the inverter/rectifier arranged between a midpoint and one of the DC terminals is in a short-circuit state, perform a fifth measurement on the electrical quantity associated with the measuring resistor,
take this fifth measurement as a basis for determining whether one of the switches of the inverter/rectifier arranged between a midpoint and the other of the DC terminals is in a short-circuit state,
when none of the switches of the inverter/rectifier arranged between a midpoint and the other of the DC terminals is in a short-circuit state, perform a sixth measurement on the electrical quantity associated with the measuring resistor,
take this sixth measurement as a basis for determining whether one phase of the AC voltage is shorted to the neutral,
when no phase of the AC voltage is shorted to the neutral, perform a seventh measurement on the electrical quantity associated with the measuring resistor,
take this seventh measurement as a basis for determining whether a short circuit exists between the first phase and the second phase of the AC voltage,
when no short circuit is detected between the first phase and the second phase of the AC voltage, perform an eighth measurement on the electrical quantity associated with the measuring resistor,
take this eighth measurement as a basis for determining whether a short circuit exists between the first phase and the third phase of the AC voltage,
when no short circuit is detected between the first phase and the third phase of the AC voltage, perform a ninth measurement on the electrical quantity associated with the measuring resistor,
take this ninth measurement as a basis for determining whether a short circuit exists between the second phase and the third phase of the AC voltage.

The steps of the method can be performed in the order in which they have just been described.

The invention will be able to be understood better from the following description of a non-limiting exemplary implementation thereof and upon studying the appended drawing, in which:

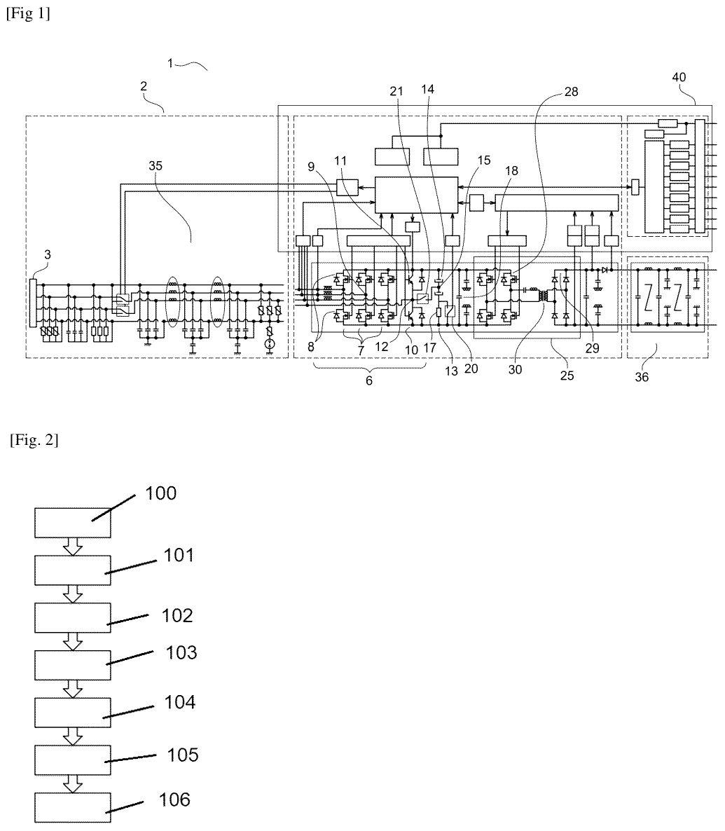

FIG. 1 schematically shows the electrical circuit of an electronic component 1 for charging an electrical energy storage unit according to an exemplary implementation of the invention,

FIG. 2 is a chart showing the various faults whose existence can be detected in the component of FIG. 1, and

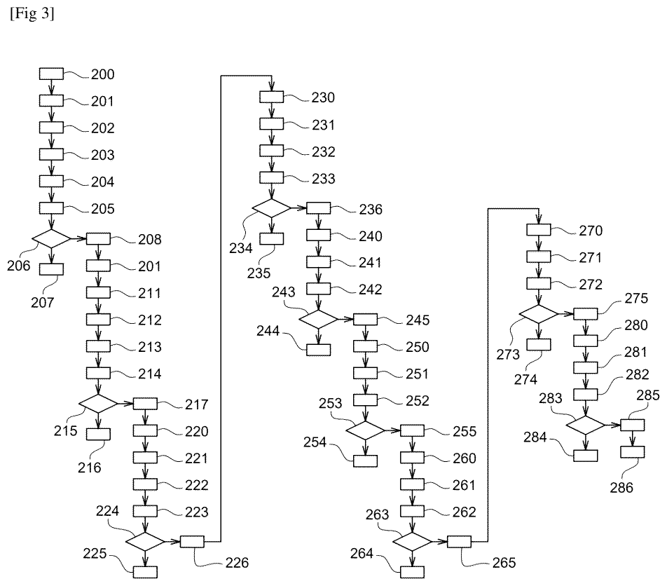

FIG. 3 shows the steps performed when the existence of the faults of FIG. 2 is detected.

FIG. 1 shows an example of an electrical circuit 2 of an electronic component 1 for charging an electrical energy storage unit, also called a “charger”. The electrical energy storage unit here is a battery used for supplying electric power to an electrical vehicle propulsion machine. This battery has, for example, a nominal voltage greater than 60 V, in particular greater than 300 V, in particular greater than 400 V, in particular greater than 800 V, or even 1000 V.

The electrical grid is, for example, a three-phase system conveying a voltage at a first frequency, which is 50 Hz or 60 Hz and whose RMS value is 230 V or 240 V. The electrical grid is connected to the electrical circuit 2 by means of a connector 3 that is shown schematically in FIG. 1.

The electrical circuit 2 comprises, in this example:
an inverter/rectifier 6, comprising three switching arms 7 connected in parallel, each switching arm 7 comprising two switches 8 arranged on either side of a midpoint 9 capable of being connected to a respective phase of the AC voltage,
a fourth switching arm 10 connected in parallel with the switching arms 7, this fourth switching arm 10 comprising two switches 11 arranged on either side of a fourth midpoint 12 capable of being connected to the neutral of the electrical grid, and
a branch 13 connected in parallel with said switching arms 7 and 10, comprising two capacitors 14 arranged on either side of a fifth midpoint 15, and a measuring resistor 17 connected in series with one of the capacitors 14. The measuring resistor 17 here is a positive temperature coefficient thermistor, also known as a PTC.

All the switches 8 here are MOSFETs and the switches 11 are IGBTs.

It can be seen that the branch 13 and the switching arms 7 and 10 are connected between two DC potential terminals. The example under consideration also shows:
that the measuring resistor 17 is connected in series between earth and the capacitor 14 arranged between the fifth midpoint 15 and earth, and
that a first switch 20 is connected in parallel with this measuring resistor 17.

The fourth midpoint 12 is also connected to the fifth midpoint 15 by means of a second switch 21.

The first switch 20 and the second switch 21 here are electrical engineering relays. As a variant, other examples are possible, for example the use of static relays based on optical couplers and/or MOSFETs and/or IGBTs.

Still in the example of FIG. 1, another capacitor 18 is connected in parallel with the branch 13.

The electrical circuit 2 also comprises a DC-to-DC converter 25 in the example of FIG. 1. Here, this DC-to-DC converter 25 comprises, in a known manner, two DC-to-AC converters 28 and 29. It can be seen in FIG. 1 that the DC-to-AC converter 28 here is reversible, using bidirectional switches that are MOSFETs, whereas the DC-to-AC converter 29 is unidirectional, being a diode rectifier here. An electrical isolation transformer 30 is arranged between these two DC-to-AC converters 28 and 29. This DC-to-DC converter is, for example, resonant, being of LLC or CLLC type, among others.

As shown in FIG. 1, an AC filtering stage 35 may be provided, this filtering stage 35 being arranged in series between the connector 3 and the inverter/rectifier 6 here. This filtering stage 35 can be used, in particular when the AC voltage is polyphase, to filter the common-mode current and to filter the differential current. As shown, relays may be present to allow toggling from a three-phase mode to a single-phase mode, and vice versa.

If necessary, and as shown in FIG. 1, another DC filtering stage 36 may be present, being then arranged in series between the DC-to-DC converter 25 and the electrical energy storage unit, as shown in FIG. 1.

The component 1 advantageously has no fuse.

The component 1 comprises a control unit 40 whose role will be described below. This control unit 40 is, for example, produced using multiple modules, as can be seen in FIG. 1. This control unit 40 comprises, for example, microcontrollers and/or integrated circuits.

In the example of FIG. 2, a low voltage is available across the terminals of the switching arms 7 and 10 in a state 100. This voltage, which is not obtained via the connector 3, is obtained from the power supply of the control unit 40 and has a value between 12 V and 24 V, for example 18 V or 20 V. The voltage across the terminals of the measuring resistor 17 can be measured by the control unit multiple times and these measurements can be used to determine:
according to 101, whether the first switch 20 is in a short-circuit state,
according to 102, whether the second switch 21 is in a short-circuit state and whether one of the switches 11 of the fourth switching arm 10 is shorted,
according to 103, whether one of the switches 8 of one of the switching arms 7 of the inverter/rectifier 6 is in a short-circuit state,
according to 104, whether a short circuit exists between one phase of the AC voltage and the neutral, and
according to 105, whether a short circuit exists between two of the three phases of the AC voltage.

It is then possible, according to 106, to make a diagnosis as to the suitability of the component 1 to be connected to the electrical grid.

The various steps that can be used to make this diagnosis will now be described with reference to FIG. 3. To carry out these steps, in the example under consideration, the control unit 40 performs a sequence of measurements on the voltage across the terminals of the measuring resistor 17 and, using these measurements, determines whether or not multiple instances of these faults exist, one measurement being associated with the determination of one or more of said faults.

The measurement is, for example, compared with a reference value by the control unit 40 and, depending on the result of this comparison, the control unit 40 determines whether or not the fault exists.

In the example of FIG. 3, according to an initialization step 200, the voltage across the terminals of the measuring resistor 17 is measured in order to obtain, according to a step 201, a first reference value, without application of an external voltage. In step 202, the control unit 40 opens the first switch 20 arranged in parallel with the measuring resistor 17. In step 203, the control device controls a switch (not shown in FIG. 1) so as to supply a DC voltage originating from the power supply of the control unit 40 to the terminals of the branch 13. This DC voltage has a value of 18 V here. A time delay, for example of 1 ms, is applied according to step 204.

In step 205, the voltage across the terminals of the measuring resistor 17 is measured, this measurement also being referred to as the “first measurement” above. In step 206, the control unit determines whether or not the voltage value measured in step 205 is the same as that measured in step 201. If they are equal, the control unit deduces in step 207 that the first switch 20 is in a short-circuit state, and it sends a message indicating that it is not possible to connect the connector 3 to the electrical grid. If they are not equal, the control unit deduces in step 208 that the first switch 20 is not in a short-circuit state. Steps 207 and 208 complete the detection of a short-circuit state of the first switch 20 by the control unit 40. When step 208 is performed, the control unit can test for a short-circuit state of the second switch 21 according to steps 210 to 217.

In step 210, a time delay, for example of 600 ms, is applied. This step 210 allows the voltage across the terminals of the measuring resistor 17 to be discharged. In step 211, a measurement on the voltage across the terminals of the measuring resistor 17 is performed to establish a reference measurement. In step 212, the control unit 40 closes the switch 11 arranged between earth and the fourth midpoint 12. In step 213, a time delay, for example of 1 ms, is applied. In step 214, a measurement on the voltage across the terminals of the measuring resistor 17 is performed by the control unit 40, this measurement also being referred to as the “second measurement” above. In step 215, the control unit 40 determines whether or not the voltage value measured in step 214 is the same as that measured in step 211. If they are not equal, the control unit deduces in step 216 that the switch 11 arranged between the fourth midpoint 12 and the terminal at the positive DC potential is in a short- circuit state or that the second switch 21 is in a short-circuit state, and it sends a message indicating that it is not possible to connect the connector 3 to the electrical grid. If they are equal, the control unit deduces in step 217 that the second switch 21 is not in a short-circuit state. Steps 216 and 217 complete the detection of a short-circuit state of the second switch 21 by the control unit 40. When step 217 is performed, the control unit can test for a short-circuit state of the switch 11 arranged between earth and the fourth midpoint 12 according to steps 220 to 226.

In step 220, a measurement on the voltage across the terminals of the measuring resistor 17 is performed to establish a reference measurement. In step 221, the control unit 40 closes the switch 11 arranged between the terminal at the positive DC potential and the fourth midpoint 12. In step 222, a time delay, for example of 1 ms, is applied. In step 223, a measurement on the voltage across the terminals of the measuring resistor 17 is performed by the control unit 40, this measurement also being referred to as the “third measurement” above. In step 224, the control unit 40 determines whether or not the voltage value measured in step 224 is the same as that measured in step 221. If they are not equal, the control unit deduces in step 225 that the switch 11 arranged between earth and the fourth midpoint 12 is in a short-circuit state, and it sends a message indicating that it is not possible to connect the connector 3 to the electrical grid. If they are equal, the control unit deduces in step 226 that the switch 11 arranged between earth and the fourth midpoint 12 is not in a short-circuit state. Steps 225 and 226 complete the detection of a short-circuit state of the switch 11 arranged between earth and the fourth midpoint 12 by the control unit 40. When step 226 is performed, the control unit can test for a short-circuit state of the switches 8 of the inverter/rectifier 6 arranged between a midpoint 9 and one of the DC potential terminals according to steps 230 to 236.

In step 230, a measurement on the voltage across the terminals of the measuring resistor 17 is performed to establish a reference measurement. In step 231, the control unit 40 closes all the switches 8 arranged between a midpoint 9 and earth. In step 232, a time delay, for example of 1 ms, is applied. In step 233, a measurement on the voltage across the terminals of the measuring resistor 17 is performed by the control unit 40, this measurement also being referred to as the “fourth measurement” above. In step 234, the control unit 40 determines whether or not the voltage value measured in step 233 is the same as that measured in step 230. If they are not equal, the control unit deduces in step 235 that one of the switches 8 arranged between the positive DC potential and a midpoint 9 is in a short-circuit state, and it sends a message indicating that it is not possible to connect the connector 3 to the electrical grid. If they are equal, the control unit deduces in step 236 that none of the switches 8 arranged between the positive DC potential and a midpoint 9 is in a short-circuit state. Steps 235 and 236 complete the detection of a short-circuit state of one of the switches 8 arranged between a midpoint and the positive DC potential by the control unit 40. When step 236 is performed, the control unit can test for a short-circuit state of the switches 8 of the inverter/rectifier 6 that are arranged between a midpoint 9 and the other of the DC potential terminals, here earth, according to steps 240 to 245.

In step 240, a measurement on the voltage across the terminals of the measuring resistor 17 is performed to establish a reference measurement. In step 241, the control unit 40 closes all the switches 8 arranged between a midpoint 9 and the positive DC potential. In step 242, a time delay, for example of 1 ms, is applied. In a step that is not shown, a measurement on the voltage across the terminals of the measuring resistor 17 is performed by the control unit 40, this measurement also being referred to as the “fifth measurement” above. In step 243, the control unit 40 determines whether or not the voltage value that has just been measured is the same as that measured in step 240. If they are not equal, the control unit deduces in step 244 that one of the switches 8 arranged between earth and a midpoint 9 is in a short-circuit state, and it sends a message indicating that it is not possible to connect the connector 3 to the electrical grid. If they are equal, the control unit deduces in step 245 that none of the switches 8 arranged between earth and a midpoint 9 is in a short-circuit state. Steps 244 and 245 complete the detection of a short-circuit state of one of the switches 8 arranged between a midpoint and earth by the control unit 40. When step 245 is performed, the control unit 40 can test for whether a short circuit exists between one phase of the AC voltage and the neutral according to steps 250 to 255.

In step 250, a measurement on the voltage across the terminals of the measuring resistor 17 is performed to establish a reference measurement. In step 251, the control unit 40 closes all the switches 8 arranged between a midpoint 9 and the positive DC potential and opens the switch 11 arranged between the fourth midpoint 12 and earth. In step 252, a time delay, for example of 1 ms, is applied. In a step that is not shown in FIG. 3, a measurement on the voltage across the terminals of the measuring resistor 17 is performed by the control unit 40, this measurement also being referred to as the “sixth measurement” above. In step 253, the control unit 40 determines whether or not the voltage value that has just been measured is the same as that measured in step 250. If they are not equal, the control unit deduces in step 254 that a short circuit exists between one of the phases and the neutral, and it sends a message indicating that it is not possible to connect the connector 3 to the electrical grid. If they are equal, the control unit deduces in step 255 that no phase is shorted to the neutral. Steps 254 and 255 complete the detection of a short circuit between one phase and the neutral by the control unit 40. When step 255 is performed, the control unit 40 can test for whether a short circuit exists between two phases of the AC voltage according to steps 260 to 265, 270 to 275 and 280 to 285.

Steps 260 to 265 relate to whether a short circuit exists between the first phase and the second phase of the AC voltage, steps 270 to 275 relate to whether a short circuit exists between the first phase and the third phase of the AC voltage and steps 280 to 285 relate to whether a short circuit exists between the second phase and the third phase of the AC voltage.

In step 260, a measurement on the voltage across the terminals of the measuring resistor 17 is performed to establish a reference measurement. In step 261, the control unit 40 closes the switch 8 of the switching arm 7 for the first phase arranged between the midpoint 9 of this arm 7 and the terminal at the positive DC potential, and closes the switch 8 of the switching arm 7 for the second phase arranged between the midpoint 9 of this arm 7 and earth. In step 262, a time delay, for example of 1 ms, is applied. In a step that is not shown in FIG. 3, a measurement on the voltage across the terminals of the measuring resistor 17 is performed by the control unit 40, this measurement also being referred to as the “seventh measurement” above. In step 263, the control unit 40 determines whether or not the voltage value that has just been measured is the same as that measured in step 260. If they are not equal, the control unit deduces in step 264 that a short circuit exists between the first phase and the second phase, and it sends a message indicating that it is not possible to connect the connector 3 to the electrical grid. If they are equal, the control unit deduces in step 265 that no short circuit exists between these two phases. Steps 264 and 265 complete the detection of a short circuit between the first phase and the second phase by the control unit 40. When step 265 is performed, the control unit 40 can test for whether a short circuit exists between the first phase and the third phase according to steps 270 to 275.

In step 270, a measurement on the voltage across the terminals of the measuring resistor 17 is performed to establish a reference measurement. In step 271, the control unit 40 closes the switch 8 of the switching arm 7 for the first phase arranged between the midpoint 9 of this arm 7 and the terminal at the positive DC potential, and closes the switch 8 of the switching arm 7 for the third phase arranged between the midpoint 9 of this arm 7 and earth. In step 272, a time delay, for example of 1 ms, is applied. In a step that is not shown in FIG. 3, a measurement on the voltage across the terminals of the measuring resistor 17 is performed by the control unit 40, this measurement also being referred to as the “eighth measurement” above. In step 273, the control unit 40 determines whether or not the voltage value that has just been measured is the same as that measured in step 270. If they are not equal, the control unit deduces in step 274 that a short circuit exists between the first phase and the third phase, and it sends a message indicating that it is not possible to connect the connector 3 to the electrical grid. If they are equal, the control unit deduces in step 275 that no short circuit exists between these two phases. Steps 274 and 275 complete the detection of a short circuit between the first phase and the third phase by the control unit 40. When step 275 is performed, the control unit 40 can test for whether a short circuit exists between the second phase and the third phase according to steps 280 to 285.

In step 280, a measurement on the voltage across the terminals of the measuring resistor 17 is performed to establish a reference measurement. In step 281, the control unit 40 closes the switch 8 of the switching arm 7 for the second phase arranged between the midpoint 9 of this arm 7 and the terminal at the positive DC potential, and closes the switch 8 of the switching arm 7 for the third phase arranged between the midpoint 9 of this arm 7 and earth. In step 282, a time delay, for example of 1 ms, is applied. In a step that is not shown in FIG. 3, a measurement on the voltage across the terminals of the measuring resistor 17 is performed by the control unit 40, this measurement also being referred to as the “ninth measurement” above. In step 283, the control unit 40 determines whether or not the voltage value that has just been measured is the same as that measured in step 280. If they are not equal, the control unit deduces in step 284 that a short circuit exists between the second phase and the third phase, and it sends a message indicating that it is not possible to connect the connector 3 to the electrical grid. If they are equal, the control unit deduces in step 285 that no short circuit exists between these two phases. Steps 284 and 285 complete the detection of a short circuit between the second phase and the third phase by the control unit 40. When step 285 is performed, the control unit 40 can move to step 286, according to which it determines that none of the aforementioned faults exist and that the connector 3 can be connected to the electrical grid.

All the test operations described with reference to FIG. 3 can have a cumulative duration of less than 1 second, for example less than 0.7 second.

The invention is not limited to what has been described with reference to the figures.

Other locations are possible for the measuring resistor 17, for example connection of this measuring resistor 17 in series with the capacitor 14 arranged between the positive DC potential and the fifth midpoint 15. A location of this measuring resistor 17 other than in series with one of the capacitors 14 is possible.

Furthermore, other measurements on the voltage across the terminals of the measuring resistor can be performed to detect a short-circuit state of one of the switches of the DC-to-AC converter 28 of the DC-to-DC converter 25. As a variant, the absence of a short circuit associated with the DC-to-AC converter 28 is detected in another way in the absence of a fuse, for example by shunts.

Furthermore still, the invention does not require a reference measurement for the voltage across the terminals of the measuring resistor 17 to be obtained for each test in order to determine whether one of the aforementioned faults exists. By way of example, only step 201 is performed and the reference measurement obtained therein is retained for all or some of the other tests, so that steps 211 and/or 220 and/or 230 and/or 240 and/or 250 and/or 260 and/or 270 and/or 280 are then not performed.

1. An electronic component for charging an electrical energy storage unit, comprising:
a connector connected to an electrical grid configured to supply a three-phase AC voltage;
an inverter/rectifier, comprising three switching arms connected in parallel, each switching arm comprising:
two switches arranged on either side of a midpoint connected to a respective phase of the AC voltage;
a fourth switching arm connected in parallel with the switching arms of the inverter/rectifier, the fourth switching arm comprising:
two switches arranged on either side of a fourth midpoint connected to a neutral of the electrical grid; and
a branch connected in parallel with said switching arms, comprising:
two capacitors arranged on either side of a fifth midpoint; and
a measuring resistor connected in series with one of the capacitors,
wherein the branch and the switching arms are connected between two DC terminals,
wherein a first switch is connected in parallel with the measuring resistor and in a second switch is connected in series between the fourth and the fifth midpoint.

2. The electronic component according to claim 1, wherein the measuring resistor is connected in series with the capacitor arranged between the fifth midpoint and one of the DC terminals is earth.

3. The electronic component according to claim 1, wherein each of the first and second switches is an electrical engineering relay.

4. The electronic component according to claim 1, further comprising a DC-to-DC converter cascaded with the fourth switching arm and the branch comprising the two capacitors and the measuring resistor.

5. The electronic component according to claim 1, wherein the measuring resistor is a thermistor.

6. The electronic component according to claim 1, further comprising a control unit configured to:
perform a measurement on an electrical quantity associated with the measuring resistor, and
determine, using the measurement, one of the following faults:
a short-circuit state of the first switch,
a short-circuit state of the second switch,
a short-circuit state of one of the switches of the fourth switching arm,
a short-circuit state of one of the switches of a switching arm of the inverter/rectifier,
a short circuit existing between one phase of the AC voltage and the neutral, or
a short circuit existing between two of the phases of the AC voltage.

7. The electronic component according to claim 6, wherein the control unit is configured to:
perform a sequence of measurements on the electrical quantity associated with the measuring resistor; and
determine, using the measurements, multiple instances of said faults, the determination of one or more of said faults based on one measurement.

8. The electronic component according to claim 7, wherein the control unit is configured to:
perform a first measurement on the electrical quantity associated with the measuring resistor;
determine whether the first switch is in a short-circuit state based on the first measurement,
perform a second measurement on the electrical quantity associated with the measuring resistor when the first switch is not in a short-circuit state;
determine whether the second switch is in a short-circuit state or whether one of the switches of the fourth switching arm is in a short-circuit state based on the second measurement;
perform a third measurement on the electrical quantity associated with the measuring resistor when the second switch is not in a short-circuit state or the switch of the fourth switching arm is not in a short-circuit state;
determine whether the other switch of the fourth switching arm is in a short-circuit state based on the third measurement;
perform a fourth measurement on the electrical quantity associated with the measuring resistor when the other switch of the fourth switching arm is not in a short-circuit state;
determine whether one of the switches of the inverter/rectifier arranged between a midpoint and one of the DC terminals is in a short-circuit state based on the fourth measurement;
perform a fifth measurement on the electrical quantity associated with the measuring resistor when none of the switches of the inverter/rectifier arranged between a midpoint and one of the DC terminals is in a short-circuit state;
determine whether one of the switches of the inverter/rectifier arranged between a midpoint and the other one of the DC terminals is in a short-circuit state;
perform a sixth measurement on the electrical quantity associated with the measuring resistor when none of the switches of the inverter/rectifier arranged between a midpoint and the other one of the DC terminals is in a short-circuit state;
determine whether one phase of the AC voltage is shorted to the neutral based on the sixth measurement;
perform a seventh measurement on the electrical quantity associated with the measuring resistor when no phase of the AC voltage is shorted to the neutral;
determine whether a short circuit exists between the first phase and the second phase of the AC voltage based on the seventh measurement;
perform an eighth measurement on the electrical quantity associated with the measuring resistor when no short circuit is detected between the first phase and the second phase of the AC voltage;
determine whether a short circuit exists between the first phase and the third phase of the AC voltage based on the eight measurement;
perform a ninth measurement on the electrical quantity associated with the measuring resistor when no short circuit is detected between the first phase and the third phase of the AC voltage; and
determine whether a short circuit exists between the second phase and the third phase of the AC voltage based on the ninth measurement.

9. The electronic component according to claims 4, wherein the control unit is configured to perform at least one additional measurement on the electrical quantity associated with the measuring resistor in order to determine the short-circuit state of a switch of a DC-DC converter.

10. The electronic component according to claim 6, wherein the electrical quantity associated with the measuring resistor being the voltage across the terminals of this measuring resistor.

11. The electronic component according to claim 1, further comprising an AC filtering stage arranged in series between the connector and the inverter/rectifier.

12. The electronic component according to claim 1, further comprising a DC filtering stage arranged in series between a DC-to-DC converter and the electrical energy storage unit.

13. A method, implemented in the electronic component according to claim 1, for detecting at least one of the following faults:
a short-circuit state of the first switch,
a short-circuit state of the second switch,
a short-circuit state of one of the switches of the fourth switching arm,
a short-circuit state of one of the switches of a switching arm of the inverter/rectifier,
a short circuit existing between one phase of the AC voltage and the neutral, or
a short circuit existing between two of the phases of the AC voltage,
the method comprising:
performing a measurement on an electrical quantity associated with the measuring resistor;
determining whether or not the fault exists; and
comparing the measurement with a reference value, based on determining whether or not the fault exists.

14. The method according to claim 13, wherein detection(s) is done while a voltage, which is not obtained via the connector, is applied to the terminals of the switching arms.

15. The method according to claim 14, wherein the voltage applied to the terminals of the switching arms is obtained from a power supply of a control unit and/or has a value lying between 12 V and 24 V.
